(19) United States
(12) Patent Application Publication
(10) Pub. No.: US 2024/0275354 A1
(43) Pub. Date: Aug. 15, 2024

(54) ACOUSTIC WAVE DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 18/525,953

(22) Filed: Dec. 1, 2023

(30) Foreign Application Priority Data
Feb. 9, 2023 (JP) 2023-018092

(51) Int. Cl. H03H 9/02; H03H 9/145; H03H 9/25

(52) U.S. Cl. CPC H03H 9/02574; H03H 9/02559; H03H 9/02637; H03H 9/145; H03H 9/25

(57) ABSTRACT

An acoustic wave device includes a support substrate, a piezoelectric layer on the support substrate, and an IDT electrode on the piezoelectric layer and including electrode fingers. Lithium niobate or lithium tantalate is used as a material of the piezoelectric layer. One of YAG, rutile, lanthanum aluminate, strontium titanate, or yttrium aluminate is used as a material of the support substrate.

### CROSS REFERENCE TO RELATED APPLICATIONS

This application claims the benefit of priority to Japanese Patent Application No. 2023-018092 filed on Feb. 9, 2023. The entire contents of this application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used for, for example, filters of cellular phones. Japanese Patent No. 5910763 discloses an example of an acoustic wave device. In the acoustic wave device, a multilayer substrate including a support substrate, a low-acoustic-velocity film, and a piezoelectric layer is preferably used, for example. An interdigital transducer (IDT) electrode is provided on the piezoelectric layer. In Japanese Patent No. 5910763, examples of a material of the piezoelectric layer include LiTaO₃, LiNbO₃, and the like. Examples of a material of the support substrate include silicon and the like.

### SUMMARY OF THE INVENTION

In the acoustic wave device in which the multilayer substrate is used as described in Japanese Patent No. 5910763, a main mode may be confined on a piezoelectric layer side. However, in the acoustic wave device in which the support substrate includes silicon, not only the main mode but also a higher-order mode is easily confined on the piezoelectric layer side. Therefore, it may be difficult to sufficiently suppress the higher-order mode which is an unnecessary wave.

Preferred embodiments of the present invention provide acoustic wave devices each capable of suppressing a higher-order mode.

An acoustic wave device according to a preferred embodiment of the present invention includes a support substrate, a piezoelectric layer on the support substrate, and an IDT electrode on the piezoelectric layer and including a plurality of electrode fingers. The piezoelectric layer includes lithium niobate or lithium tantalate. The support substrate includes one of YAG, rutile, lanthanum aluminate, strontium titanate, or yttrium aluminate.

According to preferred embodiments of the present invention, acoustic wave devices effectively suppress a higher-order mode.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front sectional view of an acoustic wave device according to a first preferred embodiment of the present invention.

FIG. 2 is a plan view of the acoustic wave device according to the first preferred embodiment of the present invention.

FIG. 3 is a diagram illustrating admittance-frequency characteristics in a first comparative example.

FIG. 4 is a diagram illustrating admittance-frequency characteristics in the first preferred embodiment of the present invention.

FIG. 5 is a diagram illustrating admittance-frequency characteristics in a second comparative example.

FIG. 6 is a diagram illustrating admittance-frequency characteristics in a first modification of the first preferred embodiment of the present invention.

FIG. 7 is a front sectional view of an acoustic wave device of a second modification of the first preferred embodiment of the present invention.

FIG. 8 is a diagram illustrating admittance-frequency characteristics in a second preferred embodiment of the present invention.

FIG. 9 is a diagram illustrating admittance-frequency characteristics in a third preferred embodiment of the present invention.

FIG. 10 is a diagram illustrating admittance-frequency characteristics in a fourth preferred embodiment of the present invention.

FIG. 11 is a diagram illustrating admittance-frequency characteristics in a fifth preferred embodiment of the present invention.

### DETAILED DESCRIPTION OF THE PREFERRED EMBODIMENTS

Hereinafter, the present invention is clarified by example preferred embodiments of the present invention being described with reference to the drawings.

It should be noted that each preferred embodiment described herein is merely an example and partial replacement or combination of configurations between different preferred embodiments is possible.

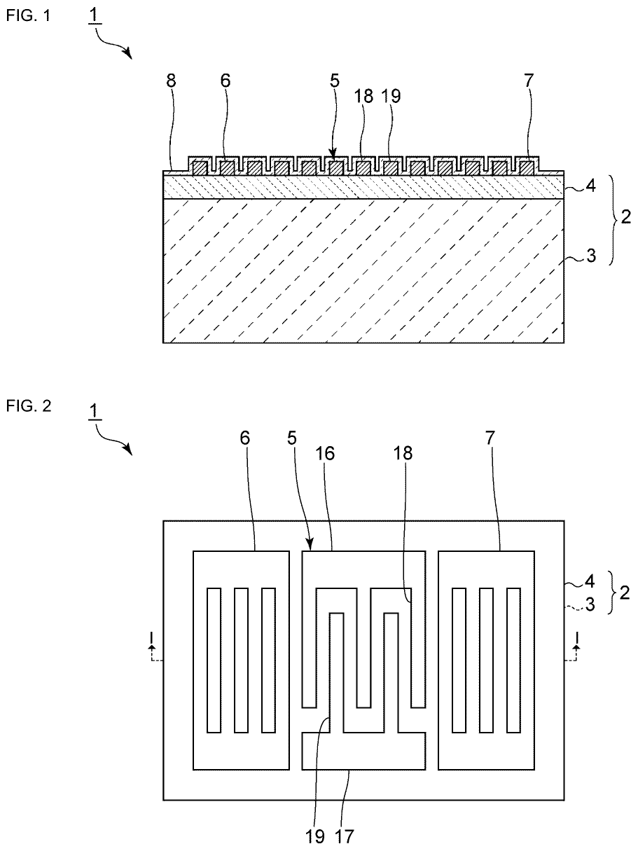

FIG. 1 is a front sectional view of an acoustic wave device according to a first preferred embodiment of the present invention. FIG. 2 is a plan view of the acoustic wave device according to the first preferred embodiment. Note that FIG. 1 is a sectional view taken along line I-I in FIG. 2. In FIG. 2, illustration of a dielectric film (described later) is omitted.

As illustrated in FIG. 1, an acoustic wave device 1 includes a piezoelectric substrate 2. More specifically, the piezoelectric substrate 2 includes a support substrate 3 and a piezoelectric layer 4. The piezoelectric layer 4 is provided on the support substrate 3. As described above, the piezoelectric substrate 2 is a substrate having piezoelectricity.

In this preferred embodiment, the piezoelectric layer 4 is provided directly on the support substrate 3. However, an intermediate layer may be provided between the support substrate 3 and the piezoelectric layer 4.

As a material of the support substrate 3, yttrium aluminum garnet (YAG) may be used, for example. Note that the material of the support substrate 3 is not limited to the above-described material. In various preferred embodiments of the present invention, one of YAG, rutile, lanthanum aluminate, strontium titanate, and yttrium aluminate may be used as the material of the support substrate 3, for example.

As a material of the piezoelectric layer 4, rotated Y cut X SAW propagation lithium tantalate may be used, for example. More specifically, as the material of the piezoelectric layer 4, rotated Y cut X SAW propagation LiTaO₃ may be used, for example. When the rotated Y cut X SAW propagation lithium tantalate is used as the material of the piezoelectric layer 4, a cut-angle of the piezoelectric layer 4 is preferably an angle within a range of about 42°±20°, for example. Note that, in various preferred embodiments of the present invention, rotated Y cut X SAW propagation lithium niobate may be used as the material of the piezoelectric layer 4, for example.

An IDT electrode 5 is provided on the piezoelectric layer 4. As illustrated in FIG. 2, the IDT electrode 5 includes a first busbar 16, a second busbar 17, a plurality of first electrode fingers 18, and a plurality of second electrode fingers 19. The first busbar 16 and the second busbar 17 are opposed to each other. One ends of the plurality of first electrode fingers 18 are connected to the first busbar 16. One ends of the plurality of second electrode fingers 19 are connected to the second busbar 17. The plurality of first electrode fingers 18 and the plurality of second electrode fingers 19 interdigitate with each other. The first electrode fingers 18 are connected to a potential different from a potential to which the second electrode fingers 19 are connected. The first electrode fingers 18 and the second electrode fingers 19 may simply be referred to below as electrode fingers.

By applying alternating-current voltage to the IDT electrode 5, an acoustic wave can be excited. Note that, in this preferred embodiment, a propagation direction of an acoustic wave and an extending direction of the pluralities of electrode fingers are perpendicular or substantially perpendicular to each other. On respective sides of the IDT electrode 5 in the propagation direction of the acoustic wave, reflectors 6 and 7 as one pair are provided on the piezoelectric layer 4. The acoustic wave device 1 is a surface acoustic wave resonator. However, the acoustic wave device according to various preferred embodiments of the present invention may be, for example, a filter device or a multiplexer including a plurality of acoustic wave resonators.

The IDT electrode 5 and each reflector are made of a multilayer metal film. Specifically, a layer configuration of the IDT electrode 5 and each reflector is a configuration in which a Ti layer, an AlCu layer, and a Ti layer are laminated in this order from a piezoelectric layer 4 side. However, the material of the IDT electrode 5 and each reflector is not limited to the above-described material. Alternatively, the IDT electrode 5 and each reflector may be made of a single metal film.

When λ is a wavelength defined by an electrode finger pitch of the IDT electrode 5, a thickness of the piezoelectric layer 4 is preferably about 1λ or smaller, for example. Therefore, excitation efficiency of an acoustic wave can be increased. However, the thickness of the piezoelectric layer 4 is not limited to be in the above-described range. Note that the electrode finger pitch is a distance between centers of a first electrode finger 18 and a second electrode finger 19 adjacent to each other. Specifically, when p is the electrode finger pitch, λ=2p is preferably satisfied, for example.

Referring back to FIG. 1, on the piezoelectric layer 4, a dielectric film 8 is provided to cover the IDT electrode 5. Therefore, the IDT electrode 5 is less likely to be damaged. In this preferred embodiment, as a material of the dielectric film 8, silicon oxide is preferably used, for example. Therefore, an absolute value of a temperature coefficient of frequency (TCF) of the acoustic wave device 1 can be made smaller. Thus, frequency-temperature characteristics of the acoustic wave device 1 can be improved. However, the material of the dielectric film 8 is not limited to the above-described material. As the material of the dielectric film 8, for example, silicon nitride, silicon oxynitride, or the like may be used. Note that the dielectric film 8 is not necessarily provided.

One of the unique features of this preferred embodiment is that lithium tantalate is used as the material of the piezoelectric layer 4 and YAG is preferably used as the material of the support substrate 3. Therefore, a higher-order mode can be suppressed. The first preferred embodiment and a first comparative example are compared to describe this effect in detail below.

The first comparative example is different from the first preferred embodiment in that a support substrate includes silicon. The first comparative example is different from the first preferred embodiment also in that the support substrate, a silicon nitride layer, a silicon oxide layer, and a piezoelectric layer are laminated in this order in a piezoelectric substrate. The acoustic wave device having the configuration of the first preferred embodiment and an acoustic wave device of the first comparative example were prepared, and admittance-frequency characteristics in each acoustic wave device were measured. Example design parameters of the acoustic wave device having the configuration of the first preferred embodiment are as follows.
Support substrate: material . . . YAG
Piezoelectric layer: material . . . rotated Y cut X SAW propagation LiTaO₃, cut-angle . . . 50°, thickness . . . 0.2λ
IDT electrode: layer configuration . . . Ti layer/AlCu layer/Ti layer from piezoelectric layer side, thickness . . . 0.006λ/0.05λ/0.002λ from piezoelectric layer side
Dielectric film: material . . . SiO₂, thickness . . . 0.015λ
Wavelength λ: 2 μm
Duty ratio of IDT electrode: 0.5

Design parameters of the acoustic wave device of the first comparative example, except for the following parameters, are the same as the above-described design parameters of the acoustic wave device having the configuration of the first preferred embodiment.
Support substrate: material . . . Si
Silicon nitride layer: thickness . . . 0.15λ
Silicon oxide layer: thickness . . . 0.15λ

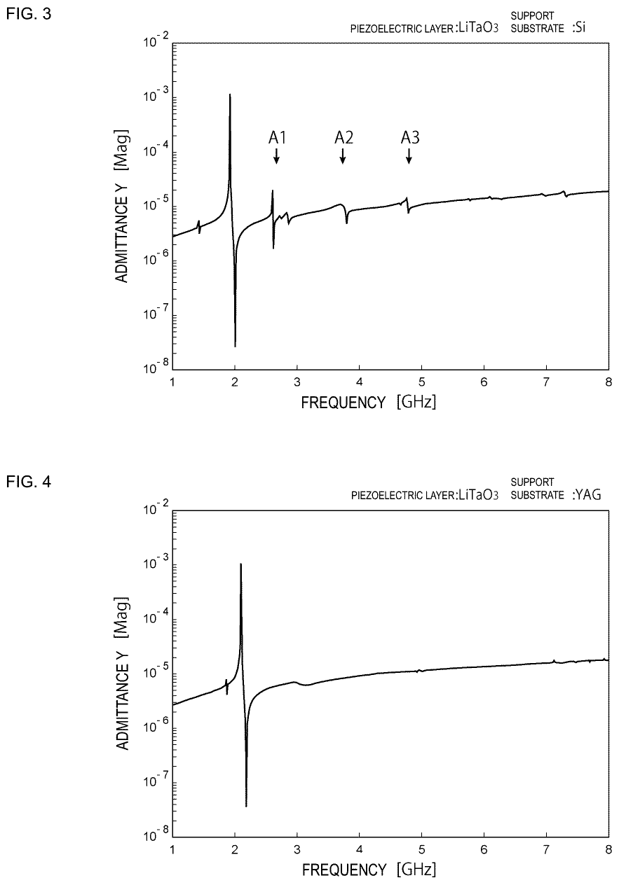

FIG. 3 is a diagram illustrating admittance-frequency characteristics in the first comparative example. FIG. 4 is a diagram illustrating admittance-frequency characteristics in the first preferred embodiment.

As illustrated in FIG. 3, in the first comparative example, a large ripple attributed to a higher-order mode occurs near frequencies indicated by arrows A1 to A3. On the other hand, as illustrated in FIG. 4, it can be seen that a higher-order mode is suppressed in the first preferred embodiment. Reasons for this are as follows.

In the first preferred embodiment illustrated in FIG. 1, as the material of the support substrate 3, YAG is preferably used, for example. When YAG is used, an acoustic velocity of a bulk wave which propagates in the support substrate 3 is lower than an acoustic velocity of a higher-order mode which propagates in the piezoelectric layer 4. Therefore, the higher-order mode can be allowed to leak from a support substrate 3 side. Thus, the higher-order mode can be suppressed. In addition, in the first preferred embodiment, the acoustic velocity of the bulk wave which propagates in the support substrate 3 is higher than an acoustic velocity of a main mode which propagates in the piezoelectric layer 4. Therefore, the main mode can be confined on the piezoelectric layer 4 side.

These are similarly applied to the case where lithium tantalate is used as the material of the piezoelectric layer 4 and the case where lithium niobate is used as the material of the piezoelectric layer 4. It is described below that the higher-order mode can be suppressed when lithium niobate is used as the material of the piezoelectric layer 4.

An acoustic wave device which is different from that of the first preferred embodiment only in that lithium niobate is used as the material of the piezoelectric layer 4 indicated with reference to FIG. 1 is an acoustic wave device of a first modification of the first preferred embodiment. Admittance-frequency characteristics of the acoustic wave device having the configuration of the first modification and admittance-frequency characteristics of an acoustic wave device of a second comparative example were compared.

The second comparative example is different from the first modification in that the support substrate includes silicon. Design parameters of the acoustic wave device having the configuration of the first modification, except for the parameters of the piezoelectric layer, are the same as the design parameters of the acoustic wave device having the configuration of the first preferred embodiment for which the admittance-frequency characteristics illustrated in FIG. 4 were obtained. Specifically, the parameters of the piezoelectric layer in the acoustic wave device having the configuration of the first modification are as follows.
Piezoelectric layer: material . . . rotated Y cut X SAW propagation LiNbO₃, cut-angle . . . 40°, thickness . . . 0.2λ

Design parameters of the acoustic wave device of the second comparative example, except that the material of the support substrate is silicon, are the same as the design parameters of the acoustic wave device having the configuration of the first modification.

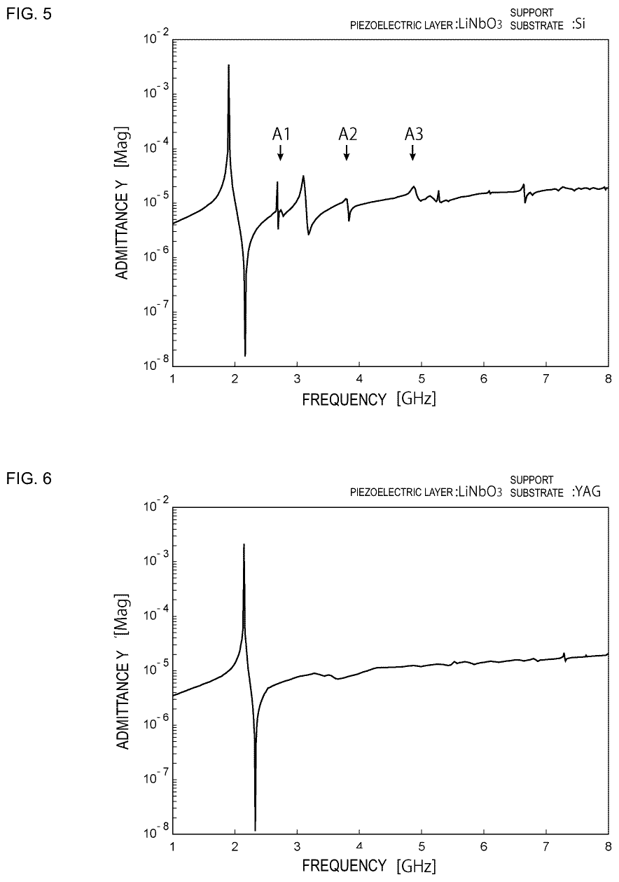

FIG. 5 is a diagram illustrating admittance-frequency characteristics in the second comparative example. FIG. 6 is a diagram illustrating admittance-frequency characteristics in the first modification of the first preferred embodiment.

As illustrated in FIG. 5, in the second comparative example, a large ripple attributed to a higher-order mode occurs near frequencies indicated by arrows A1 to A3. On the other hand, as illustrated in FIG. 6, it can be seen that a higher-order mode is suppressed in the first modification.

Note that when rotated Y cut X SAW propagation lithium niobate is used as the material of the piezoelectric layer, a cut-angle of the piezoelectric layer is preferably an angle within a range of about 30°±20°, for example.

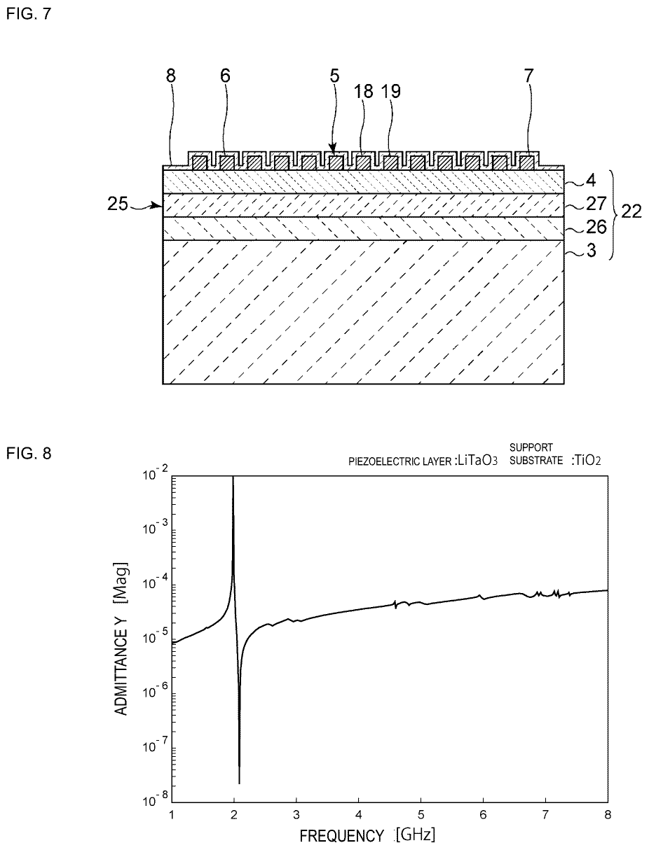

As illustrated in FIG. 1, in the first preferred embodiment, the piezoelectric layer 4 is provided directly on the support substrate 3. However, the multilayer structure of the piezoelectric substrate 2 is not limited to the above-described structure. For example, in a second modification of the first preferred embodiment illustrated in FIG. 7, an intermediate layer 25 is provided between the support substrate 3 and the piezoelectric layer 4. That is, the piezoelectric layer 4 is provided indirectly on the support substrate 3 with the intermediate layer 25 interposed therebetween.

In this modification, the intermediate layer 25 is a multilayer body. Specifically, the intermediate layer 25 includes a first layer 26 and a second layer 27. In a piezoelectric substrate 22, the first layer 26 is provided on the support substrate 3. The second layer 27 is provided on the first layer 26. The piezoelectric layer 4 is provided on the second layer 27.

As a material of the first layer 26 of the intermediate layer 25, silicon nitride is preferably used, for example. As a material of the second layer 27, silicon oxide is preferably used, for example. However, the material of each layer of the intermediate layer 25 is not limited to the above-described material.

The number of layers included in the intermediate layer 25 is not limited to two layers. For example, the intermediate layer 25 may be a single dielectric layer. Alternatively, the intermediate layer 25 may include three or more layers.

The intermediate layer 25 in this modification includes the second layer 27 as a silicon oxide layer. Note that, for example, when the intermediate layer 25 is a single dielectric layer, the intermediate layer 25 may be a silicon oxide layer. As described above, the intermediate layer 25 preferably includes a layer for which silicon oxide is used as the material. Therefore, an absolute value of a temperature coefficient of frequency of the acoustic wave device can be made smaller, and frequency-temperature characteristics of the acoustic wave device can be improved.

Examples in which only the material of the support substrate 3 is different from that in the first preferred embodiment are described below in second to fifth preferred embodiments. In description of the second to fifth preferred embodiments, the same drawings and reference numerals used in the description of the first preferred embodiment are used. Also in the second to fifth preferred embodiments, similarly to the first preferred embodiment, the main mode can be confined on the piezoelectric layer 4 side, and the higher-order mode can be suppressed. Note that, in the second to fifth preferred embodiments, lithium tantalate is preferably used as the material of the piezoelectric layer 4, for example. Note that also in the case where lithium niobate is used as the material of the piezoelectric layer 4, the main mode can be confined on the piezoelectric layer 4 side and the higher-order mode can be suppressed.

In the second preferred embodiment, as the material of the support substrate 3, rutile is preferably used, for example. More specifically, as the material of the support substrate 3, TiO₂ having a rutile crystal structure is preferably used, for example.

In the third preferred embodiment, as the material of the support substrate 3, lanthanum aluminate is preferably used, for example. More specifically, as the material of the support substrate 3, LaAlo₃ is preferably used, for example.

In the fourth preferred embodiment, as the material of the support substrate 3, strontium titanate is preferably used, for example. More specifically, as the material of the support substrate 3, SrTiO₃ is preferably used, for example.

In the fifth preferred embodiment, as the material of the support substrate 3, yttrium aluminate is preferably used, for example. More specifically, as the material of the support substrate 3, YAlO₃ is preferably used, for example.

Admittance-frequency characteristics of the acoustic wave device having the configuration of each of the second to fifth preferred embodiments were obtained. Note that design parameters of each of the acoustic wave devices, except for the material of the support substrate, are the same as the design parameters of the acoustic wave device having the configuration of the first preferred admittance-frequency embodiment for which the characteristics illustrated in FIG. 4 were obtained.

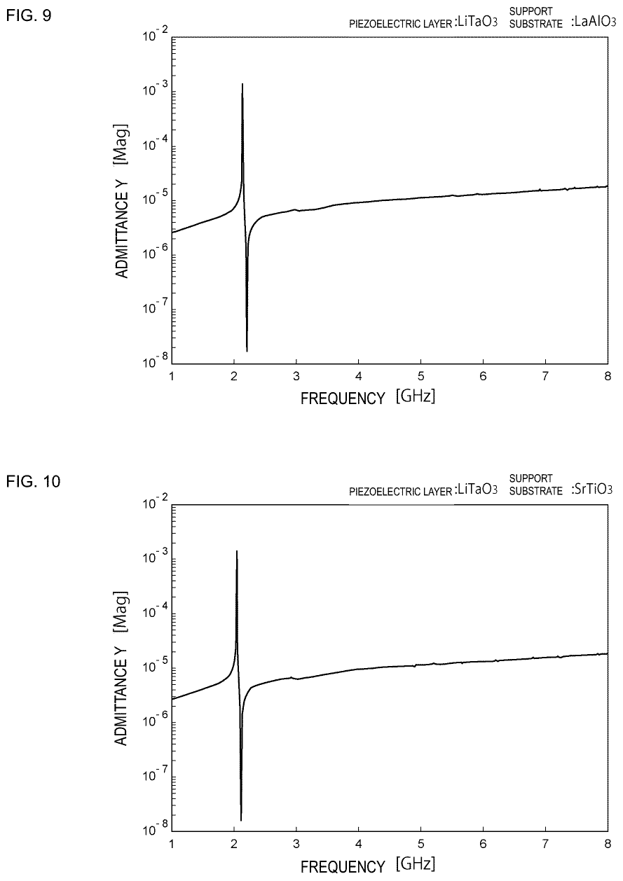

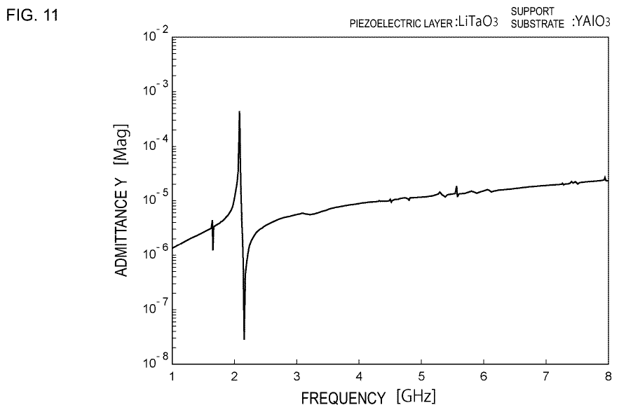

FIG. 8 is a diagram illustrating admittance-frequency characteristics in the second preferred embodiment. FIG. 9 is a diagram illustrating admittance-frequency characteristics in the third preferred embodiment. FIG. 10 is a diagram illustrating admittance-frequency characteristics in the fourth preferred embodiment. FIG. 11 is a diagram illustrating admittance-frequency characteristics in the fifth preferred embodiment.

As illustrated in FIG. 8, it can be seen that the higher-order mode is suppressed in the second preferred embodiment. Similarly, as illustrated in FIGS. 9 to 11, it can be seen that the higher-order mode is suppressed also in the third to fifth preferred embodiments.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
a piezoelectric layer on the support substrate; and
an IDT electrode on the piezoelectric layer and including a plurality of electrode fingers; wherein
the piezoelectric layer includes lithium niobate or lithium tantalate; and
the support substrate includes one of YAG, rutile, lanthanum aluminate, strontium titanate, or yttrium aluminate.

2. The acoustic wave device according to claim 1, wherein the support substrate includes YAG.

3. The acoustic wave device according to claim 1, wherein the support substrate includes rutile.

4. The acoustic wave device according to claim 1, wherein the support substrate includes lanthanum aluminate.

5. The acoustic wave device according to claim 1, wherein the support substrate includes strontium titanate.

6. The acoustic wave device according to claim 1, wherein the support substrate includes yttrium aluminate.

7. The acoustic wave device according to claim 1, wherein when λ is a wavelength defined by an electrode finger pitch of the IDT electrode, a thickness of the piezoelectric layer is about 1λ or smaller.

8. The acoustic wave device according to claim 1, wherein the piezoelectric layer includes rotated Y cut X SAW propagation lithium tantalate, and a cut-angle of the piezoelectric layer is an angle within a range of about 42°±20°.

9. The acoustic wave device according to claim 1, wherein the piezoelectric layer includes rotated Y cut X SAW propagation lithium niobate, and a cut-angle of the piezoelectric layer is an angle within a range of about 30°±20°.

10. The acoustic wave device according to claim 1, further comprising:
an intermediate layer between the support substrate and the piezoelectric layer; wherein
the intermediate layer includes a silicon oxide layer.

11. The acoustic wave device according to claim 1, wherein the acoustic wave device is a surface acoustic wave resonator.

12. The acoustic wave device according to claim 1, wherein the acoustic wave device is a filter device.

13. The acoustic wave device according to claim 1, wherein the acoustic wave device is a multiplexer.

14. The acoustic wave device according to claim 1, further comprising reflectors provided on opposite sides of the IDT electrode.

15. The acoustic wave device according to claim 14, wherein each of the reflectors is defined by a single metal film.

16. The acoustic wave device according to claim 14, wherein each of the reflectors is a multilayer metal film.

17. The acoustic wave device according to claim 14, wherein each of the reflectors and the IDT electrode include a Ti layer, an AlCu layer, and a Ti layer in this order.

18. The acoustic wave device according to claim 10, wherein the intermediate layer is defined by a single layer.

19. The acoustic wave device according to claim 10, wherein the intermediate layer is defined by a plurality of layers.
